(19) United States
(12) Patent Application Publication
(10) Pub. No.: US 2008/0174326 A1
(43) Pub. Date: Jul. 24, 2008

(54) PROBE, PROBE ASSEMBLY AND PROBE CARD FOR ELECTRICAL TESTING

(75) Inventors: Byung-Hee Jeon, Seongnam-Si (KR); Dae-Cheol Kang, Namyangju-Si (KR)

Correspondence Address: KNOBBE MARTENS OLSON & BEAR LLP, 2040 MAIN STREET, FOURTEENTH FLOOR, IRVINE, CA, 92614, US

(73) Assignee: NICTECH CO., LTD., SEOUL (KR)

(21) Appl. No.: 12/018,760

(22) Filed: Jan. 23, 2008

(30) Foreign Application Priority Data
Jan. 23, 2007 (KR) 10-2007-0007192
Jan. 23, 2007 (KR) 10-2007-0007193

(51) Int. Cl. G01R 31/02

(52) U.S. Cl. 324/754

(57) ABSTRACT

A probe card for transmitting electric signals between a test head and an inspection object includes a printed circuit board provided with a plurality of electrode pads, a supporter attached to the printed circuit board and a plurality of probes attached to the support in a removable manner. The supporter includes a pair of banks, a channel formed between the banks and a plurality of insertion slots formed on a lower surface and opposite lateral surfaces of the supporter. Each of the probes includes a first arm portion fitted to each of the insertion slots on the opposite lateral surfaces of the supporter, a second arm portion extending from a first end of the first arm portion toward the channel, a connection terminal portion provided at a second end of the first arm portion and a contact terminal portion provided at a tip end of the second arm portion.

### CROSS-REFERENCE TO RELATED APPLICATIONS

This application claims the benefit of Korean Patent Application No. 10-2007-0007192, filed on Jan. 23, 2007 and Korean Patent Application No. 10-2007-0007193, filed Jan. 23, 2007, in the Korean Intellectual Property Office, the disclosures of which are incorporated herein by reference in their entirety.

### BACKGROUND

1. Field

The present disclosure relates to a probe card and, more particularly, to a probe for use in testing electrical characteristics of an inspection object such as a semiconductor wafer, a flat display or the like and a probe card having the probe

2. Description of the Related Technology

Semiconductor devices are manufactured through a variety of processes including wafer production, wafer test, die packaging and so forth. The wafer test refers to a so-called electrical die sorting test for testing electrical characteristics of the semiconductor devices. In the electrical die sorting test, the semiconductor devices are sorted into acceptable products and unacceptable products by bringing probe pins of a probe card into contact with electrode pads of the semiconductor devices and then allowing an electric current to flow through the electrode pads of the semiconductor devices. In addition to testing the semiconductor devices, the probe card is used in testing data/gate lines in a cell process of flat displays such as a TFT-LCD (thin film transistor-liquid crystal display), a PDP (plasma display panel), an OEL (organic electroluminescence) and the like.

U.S. Pat. Nos. 7,150,095 and 7,138,812 disclose probe cards in which needle type probes are connected to a printed circuit board. Each of the probe cards disclosed in these patent documents includes a supporter for supporting probes on a printed circuit board. The probes are fixed to the supporter by means of an insulating material and electrically connected to the printed circuit board by soldering.

The foregoing discussion is to provide background information of the invention and does not constitute an admission of prior art.

### SUMMARY

One aspect of the invention provides a probe card for electrical testing. The probe card comprises: a probe supporter comprising a first side surface and a first bottom surface; a plurality of insertion slots formed into at least one of the first side surface and the first bottom surface of the support; a plurality of probes. A first one of the plurality of probes comprises: a first arm extending along the first side surface, a second arm connected to the first arm and extending along the first bottom surface, a first terminal portion formed at a distal end of the first arm and comprising a first tip configured to contact a first electrode, and a second terminal portion formed at a distal end of the second arm and comprising a second tip configured to contact a second electrode. At least part of the first and second arms is inserted into a first one of the plurality of insertion slots.

In the foregoing probe card, the first insertion slot may comprise a first slot portion formed into the first side surface and a second slot portion formed into the first bottom surface, wherein a portion of the first arm may be received in the first slot portion, and wherein a portion of the second arm may be received in the second slot portion. The probe card may further comprise a printed circuit board, wherein the first electrode may be electrically connected to the printed circuit board, wherein the first tip may not be fixed to the first electrode while contacting the first electrode. The probe card may further comprise: a space transformer placed between the printed circuit board and the supporter, wherein the first electrode may belong to the space transformer while electrically connected to the printed circuit board. The probe card may further comprise an interposer placed between the printed circuit board and the space transformer for electrically interconnecting the printed circuit board and the space transformer.

Further, the second electrode may belong to an object for a test using the probe card. The supporter may comprise a first bank and a second bank, the first bank comprising the first bottom surface, the second bank comprising a second bottom surface, wherein the first and second banks may be spaced apart from each other and form a channel therebetween. The supporter may further comprise a second side surface, wherein the probe card may further comprise a plurality of insertion slots formed into at least one of the second side surface and the second bottom surface, wherein at least part of a second one of the plurality of probes may be inserted into one of the insertion slots formed in the second side surfaced and the second bottom surface. The second arm may comprise an upper surface facing the first bottom surface, wherein the second arm may comprise a recessed portion in the upper surface so as to reduce a physical contact between the first bottom surface and the upper surface of the second arm.

Still in the probe card, wherein the first probe may further comprise a first elastically deformable hinge portion generally in a juncture where the first and second arms meet with each other. The first terminal portion may further comprise a spring between the first arm and the first tip. The second terminal portion may comprise a resilient extension between the second arm and the second tip. The second terminal portion may further comprise a reinforcing portion configured to reinforce the resilient extension such that the resilient extension can maintain its original configuration when no external force may be exerted onto the resilient extension. The reinforcing portion may comprise a first extension and a second extension that form a generally triangular configuration together with at least part of the resilient extension. The first extension extends from about the distal end of the second arm generally perpendicular to the second arm, wherein second extension interconnects the first extension and a mid portion of the resilient extension. The first probe may further comprise a second elastically deformable hinge portion generally in a juncture where the second arm and the first extension meet with each other. The first probe may be fixed to the insertion slot by means of an insulating resin.

Another aspect of the invention provides a probe assembly for electrical testing. The probe assembly comprises: a printed circuit board; a plurality of electrode pads electrically connected to the printed circuit board; a plurality of probe cards. Each probe card comprises a probe supporter comprising a first side surface and a first bottom surface; a plurality of insertion slots formed into at least one of the first side surface and the first bottom surface of the support; a plurality of probes. A first one of the plurality of probes comprises: a first arm extending along the first side surface, a second arm connected to the first arm and extending along the first bottom surface, a first terminal portion formed at a distal end of the first arm and comprising a first tip configured to contact one of the plurality of electrode pads, wherein the first tip is not fixed to the electrode pad while contacting thereto, and a second terminal portion formed at a distal end of the second arm and comprising a second tip configured to contact an electrode of a testing object, wherein at least part of the first and second arms is inserted into a first one of the plurality of insertion slots.

Another aspect of the invention provides a method of replacing a probe card. The method comprises: providing the foregoing probe assembly; removing one of the probe cards from the probe assembly, wherein removing does not involve cutting or heating any portion of the probe card that may be being removed; and placing a new probe card into the space from which the one probe card has been removed.

A further aspect of the invention provides a probe for use in a probe card for electrical testing. The probe comprises: a first arm extending generally in a first direction; a second arm connected to the first arm and extending generally in a second direction other than the first angle; a first terminal portion formed at a distal end of the first arm and comprising a first tip configured to form an electrical and physical contact with an electrode of a first device, wherein the first terminal portion is configured to allow the first tip to elastically move generally in the first direction; and a second terminal formed at a distal end of the second arm and comprising a second tip configured to form an electrical and physical contact with an electrode of a second device, wherein the second terminal portion is configured to allow the second tip to elastically move generally in the first direction.

In the foregoing probe, the second arm has an upper surface and a cutout formed into the upper surface. The probe may further comprise a first elastically deformable hinge provided generally at a juncture where the first and second arms meet with each other. The first terminal portion may comprise a spring between the first arm and the first tip, wherein the spring may be configured to allow elastic movement of the first tip generally in the first direction. The second terminal portion may comprise a resilient extension between the second arm and the second tip. The second terminal portion may further comprise a reinforcing portion configured to reinforce the resilient extension such that the resilient extension can maintain its original configuration when no external force may be exerted onto the resilient extension. The reinforcing portion may comprise a first extension and a second extension that form a generally triangular configuration together with at least part of the resilient extension. The first extension extends from about the distal end of the second arm generally perpendicular to the second arm, wherein second extension interconnects the first extension and a mid portion of the resilient extension. The first probe may further comprise a second elastically deformable hinge portion generally in a juncture where the second arm and the first extension meet with each other.

One aspect of the present invention to provide a probe which is easy to fix in position and can be manufactured with reduced production cost and greatly increased productivity, and a probe card having the probe. Another aspect of the present invention is to provide a highly reliably probe that can be accurately connected to an inspection object and a printed circuit board, and a probe card having the probe. A further aspect of the present invention is to provide a probe capable of maintaining stable connection to each electrode pad of a printed circuit board, and a probe card having the probe. A still further aspect of the present invention is to provide a probe that can save maintenance and repair cost by making it possible to readily remove itself and a supporter thereof from a printed circuit board, and a probe card having the probe.

In one aspect of the present invention, there is provided a probe card for transmitting electric signals between a test head and electrode pads of an inspection object. The probe card comprises a printed circuit board connected to the test head and provided with a plurality of electrode pads; a supporter attached to the printed circuit board, the supporter having a lower surface and opposite lateral surfaces, the supporter including a pair of banks provided on the lower surface, a channel formed between the banks on the lower surface and a plurality of spaced-apart insertion slots formed on the lower surface and the opposite lateral surfaces; and a plurality of probes inserted into the insertion slots, each of the probes including a first arm portion fitted to each of the insertion slots on the opposite lateral surfaces of the supporter, a second arm portion extending from a first end of the first arm portion toward the channel, a connection terminal portion provided at a second end of the first arm portion so that the connection terminal portion can be connected to each of the electrode pads of the printed circuit board and a contact terminal portion provided at a tip end of the second arm portion for making contact with each of the electrode pads of the inspection object.

In another aspect of the present invention, there is provided a probe card for transmitting electric signals between a test head and electrode pads of an inspection object. The probe card comprises a printed circuit board connected to the test head and provided with a plurality of electrode pads; a supporter attached to the printed circuit board, the supporter having a lower surface and opposite lateral surfaces, the supporter including a pair of banks provided on the lower surface, a channel formed between the banks on the lower surface and a plurality of spaced-apart insertion slots formed on the lower surface and the opposite lateral surfaces; a plurality of probes inserted into the insertion slots, each of the probes including a first arm portion fitted to each of the insertion slots on the opposite lateral surfaces of the supporter, a second arm portion extending from a first end of the first arm portion toward the channel, a connection terminal portion provided at a second end of the first arm portion so that the connection terminal portion can be connected to each of the electrode pads of the printed circuit board and a contact terminal portion provided at a tip end of the second arm portion for making contact with each of the electrode pads of the inspection object; a space transformer mounted between the printed circuit board and the supporter, the space transformer provided with a plurality of electrode pads, the connection terminal portion of each of the probes connected to each of the electrode pads of the space transformer; and an interposer mounted between the printed circuit board and the space transformer for electrically interconnecting the printed circuit board and the space transformer.

In a further aspect of the present invention, there is provided a probe for use in a probe card for transmitting electric signals between a printed circuit board and electrode pads of an inspection object. The probe comprises a first arm portion; a second arm portion extending from a first end of the first arm portion in an angled relationship with the first arm portion; a connection terminal portion provided at a second end of the first arm portion so that the connection terminal portion can be electrically connected to the printed circuit board; and a contact terminal portion provided at a tip end of the second arm portion for making contact with each of the electrode pads of the inspection object.

### BRIEF DESCRIPTION OF THE DRAWINGS

The above and other features of the present invention will become apparent from the following description of preferred embodiments, given in conjunction with the accompanying drawings, in which:

FIG. 1 is an exploded perspective view schematically showing a probe card in accordance with one embodiment of the present invention;

FIG. 2 is a schematic perspective view illustrating a probe assembly of the probe card of FIG. 1;

FIG. 3 is a schematic section view illustrating the probe assembly of the probe card of FIG. 1;

FIG. 4 is a side elevational view showing the probe card of FIG. 1;

FIG. 5 is an exploded perspective view schematically showing a probe card in accordance with another embodiment of the present invention; and

FIG. 6 is a schematic section view illustrating a probe assembly of the probe card of FIG. 5.

### DETAILED DESCRIPTION OF EMBODIMENT

Various embodiments in accordance with the present invention will now be described in detail with reference to the accompanying drawings.

A probe card for electrical testing includes a plurality of probes for making direct contact with electrode pads of a wafer to be tested, a supporter for supporting the probes, and a printed circuit board for transmitting electric signals between the test head of a tester and the probes. It is sometimes the case that a space transformer and an interposer are provided between the probes of the probe card and the printed circuit board. The space transformer serves to ensure that the probes are electrically connected to the printed circuit board in a smooth manner during the process of arranging the probes at a fine pitch. The interposer has a function of transmitting electrical signals between the printed circuit board and the space transformer, while keeping the probe card planar.

While probe cards have been known for some time, the probes need to be aligned with the supporter through the use of a probe-positioning jig in order for a worker to fix the probes to the supporter, and soldering has to be performed to bond the probes to the printed circuit board. This sharply reduces the manufacturing productivity of the probe cards and makes it difficult to control the planarity of the probes.

Furthermore, the prior art probe cards makes it difficult to repair or replace the probes on a one-for-one basis because the probes are soldered to the printed circuit board. In other words, when one of the probes is defective, it is impossible to remove only the defective probe. There is no choice but to replace the probe card having the defective probe as a whole. Moreover, individual probes have been coated with an insulating material one by one in order to prevent short-circuit of the probes, which leads to increased production cost and reduced productivity.

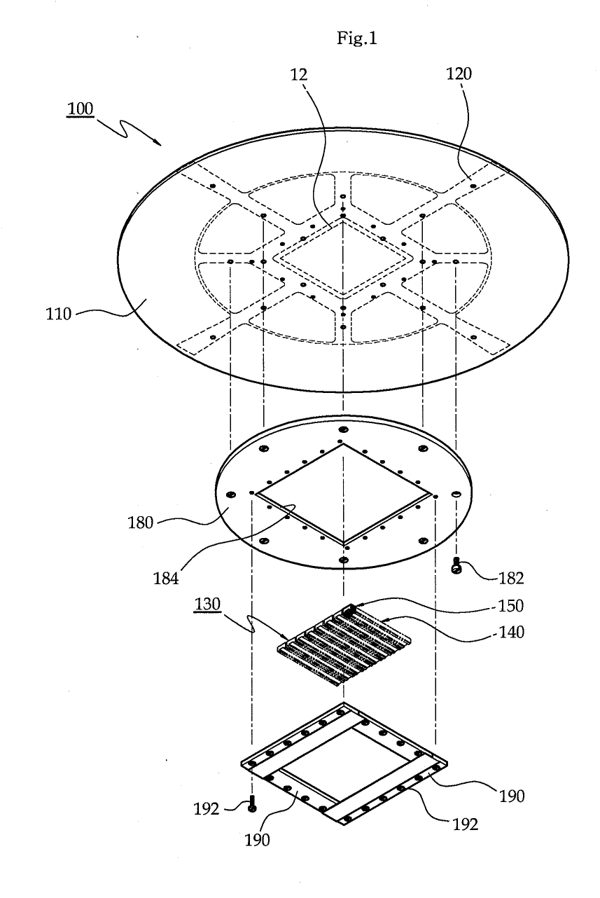

Shown in FIG. 1 is a probe card 100 in accordance with one embodiment of the present invention. Referring to FIG. 1, the probe card 100 includes a printed circuit board 110, a stiffener 120 and a plurality of probe assemblies 130. The printed circuit board 110 is connected to a test head (not shown) of a tester through a pogo block and a performance board unit, both of which are well-known in the art. The printed circuit board 110 is provided with a plurality of electrode pads 112 on its lower surface. The stiffener 120 is attached to an upper surface of the printed circuit board 110 to increase the rigidity thereof and also to keep the same planar.

Referring to FIGS. 1 to 3, each of the probe assemblies 130 includes a supporter 140 attached to the lower surface of the printed circuit board 110 and a plurality of probes 150 fixed to the supporter 140. The supporter 140 is made of an insulating material, e.g., a ceramic material such as zirconia (ZrO₂) or the like. In one embodiment, the supporter 140 may be made of various kinds of materials other than the ceramic material.

The supporter 140 is configured to support, hold and/or fix a plurality of probes such that the neighboring probes are arranged with a predetermined interval. The supporter 140 includes a plurality of slots or grooves configured to engage with the probes. The slots are arranged so as to provide the predetermined intervals to the probes engaged with the slots.

In the illustrated embodiment, the supporter 140 includes two side (or lateral) surfaces 141a and 141b and two bottom banks 142a and 142b, although not limited thereto. The bottom banks 142a and 142b extend in the longitudinal direction of the supporter 140 and form a longitudinally extending channel 144 between them. The side surface 141a and the bottom surface of the bottom bank 142a form a corner section therebetween. The planes of the side surface and the bottom surface of the bottom bank form an angle of about 90° although not limited thereto.

A plurality of slots 146 are formed into the side surfaces 141a and 141b and the bottom banks 142a and 142b. The slots' generally vertical portions (first slot portions) 146a are formed into the side surfaces 141a and 141b. The slots' generally horizontal portions (second slot portions) 146b are formed into the bottom banks 142a and 142b. The first slot portion 146a and the second slot portion 146b are aligned and joined together. The insertion slots 146 are spaced apart from one another in the longitudinal direction of the supporter 140. Two neighboring slots have a predetermined interval therebetween so that two neighboring probes, once fixed to the supporter 140, have an appropriate distance therebetween.

In some embodiments, all or part of the insertion slots 146 may be formed of the first slot portion 146a alone, without the second slot portion 146b on the banks 142a and 142b. The first slot portion 146a and the second slot portion 146b generally make a right angle relative to each other in the illustrated embodiment, although not limited thereto. Alternatively, the angle between the first slot portion 146a and the second slot portion 146b may form an angle other than the right angle.

A pair of screw holes 148 is formed in the opposite longitudinal end portions of the supporter 140. The supporter 140 is firmly secured to the lower surface of the printed circuit board 110, for example, by tightening a pair of screws 114 into the screw holes 148 through the thickness of the printed circuit board 110. Although the supporter 140 has an elongated rod shape in the illustrated embodiment, the shape and size of the supporter 140 can vary in various embodiments.

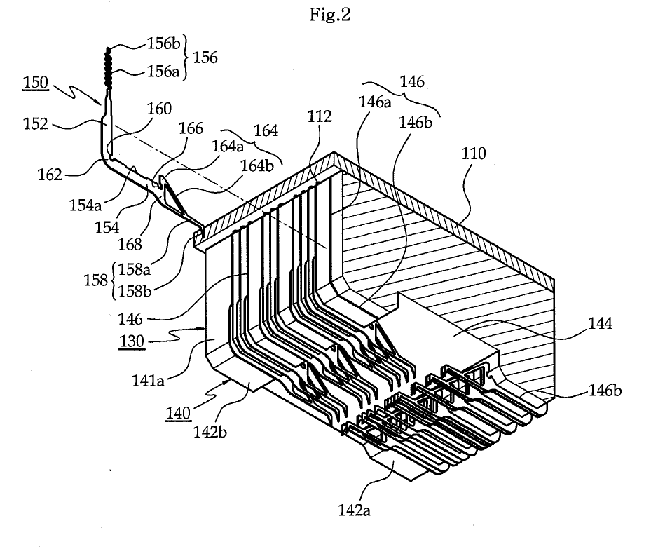

Referring to FIGS. 2 to 4, the probes 150 are inserted and fitted into the insertion slots 146 of the supporter 140. Each probe 150 is electrically connected to the printed circuit board 110 at one end and is brought into contact with electrode pads 4 of an inspection object 2 such as a semiconductor wafer, a flat display or the like at the other end. In the illustrated embodiment, the probe 150 includes a first (vertical) arm portion 152, a second (horizontal) arm portion 154 generally perpendicularly extending from a lower end of the first arm portion 152, a connection terminal portion 156 formed on an upper end of the first arm portion 152 and a contact terminal portion 158 formed on the tip end of the second arm portion 154. Although the first arm portion 152 and the second arm portion 154 make a right angle relative to each other in the illustrated embodiment, the present invention is not limited thereto. Alternatively, the second arm portion 154 may extend from the lower end of the first arm portion 152 at arbitrary angles other than the right angle.

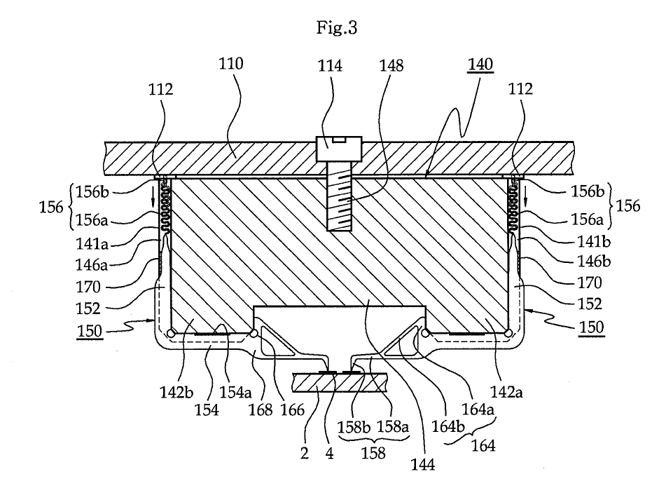

The first arm portion 152 is inserted and fitted into the first slot portion 146a of the supporter 140, while the second arm portion 154 is inserted and fitted into the second slot portion 146b of the supporter 140. A cutout or a recess 154a is formed in the upper part, e.g., generally in the center of the second arm's extension, of the second arm portion 154. As shown in FIG. 3, when the second arm portion 154 is inserted and fitted into the second slot portion 146b, only the upper peripheral regions of the second arm portion 154 except the cutout 154a make contact with the lower surface of the supporter 140, which reduces the contact area between the supporter 140 and the second arm portion 154. Therefore, a fabricating error attributable to a machining error of the insertion slots 146 and the second arm portions 154 are minimized when fitting the probes 150 to the supporter 140.

In a juncture where the first and second arm portions 152 and 154 meet with each other, a first recess 160 is formed to provide a first hinge portion 162. Presence of the first recess 160 reduces the thickness of the corner portion, thereby making the first hinge portion 162 substantially elastically deformable. The connection terminal portion 156 extends upwardly along the first slot portion 146a of the supporter 140 and makes contact with on of the electrode pads 112 of the printed circuit board 110. The connection terminal portion 156 extends from the upper end of the first arm portion 152 and includes a spring 156a and a first terminal 156b formed in the tip end portion of the spring 156a. The first terminal 156b is designed to contact one of the electrode pads 112 of the printed circuit board 110.

On the other hand, the contact terminal portion 158 includes an elongated resilient arm 158a extending from the tip end portion of the second arm portion 154 and a second terminal 158b formed in the distal end portion of the resilient arm 158a. The second terminal 158b is designed to make contact with one of the electrode pads 4 of the inspection object 2. A reinforcing portion 164 is provided to reinforce the resilient arm 158a of the contact terminal portion 158.

The reinforcing portion 164 includes a protrusion (or an upward extension portion) 164a extending vertically upwardly from the tip end portion of the second arm portion 154, although not limited to this configuration. Further, the reinforcing portion 164 includes a connecting arm portion 164b for interconnecting the middle portion of the resilient arm 158a and the top end of the upward extension portion 164a, although not limited to this configuration. The second arm portion 154, the resilient arm 158a and the connecting arm portion 164b make a triangle when the probe 150 is seen from the side thereof. Although the upward extension portion 164a extends at a right angle from the second arm portion 154 in the illustrated embodiment, the present invention is not limited thereto. Alternatively, the upward extension portion 164a may extend upwardly from the second arm portion 154 at an angle other than the right angle.

In a juncture where the second arm portion 154 and the upward extension portion 164a meet with each other, a second recess 166 is formed to provide a second hinge portion 168. Presence of the second recess 166 reduces thickness of the second hinge portion 168 in that position, thereby making the second hinge portion 168 substantially elastically deformable. The first and second arm portions 152 and 154 of each of the probes 150 are fixedly secured to the corresponding one of the insertion slots 146 of the supporter 140 by means of an insulating resin 170. Various kinds of adhesive resins including an epoxy resin may be used to fix the probes 150 to the supporter 140 as the insulating resin 170.

As can be seen in FIG. 1, the probe card 100 further includes a holder bracket 180 and a plurality of guard members 190, both of which cooperate to hold and protect the supporters 140. The holder bracket 180 is fastened to the lower surface of the printed circuit board 110 by a plurality of screws 182, although not limited thereto. A space or opening 184 for receiving the supporters 140 is formed in the central region of the holder bracket 180. The guard members 190 are secured to the lower surface of the holder bracket 180 by a plurality of screws 192, although not limited thereto, so that they can surround the edge portions of the supporters 140 received in the opening 184. Although four guard members 190 are combined to form a rectangle in the embodiment shown in FIG. 1, the present invention is not limited thereto. A single piece rectangular frame that surrounds the edge portions of the supporters 140 may be used in replacement of the guard members 190.

Description will now be made regarding a fabricating method and an operation of the probe card of the embodiment configured as above. Referring to FIGS. 1 to 3, the probe assemblies 130 are first fabricated in order to produce the probe card 100. During the process of fabricating the probe assemblies 130, the first and second arm portions 152 and 154 of the probe 150 are inserted and fitted into the corresponding one of the insertion slots 146 of the supporter 140. The other probes 150 are engaged with the supporter 140 in the same manner. Then, the probes 150 are fixedly secured to the insertion slots 146 by applying the insulating resin 170 thereto. At this time, the contact terminal portions 158 of the probes 150 are positioned in the channel 144 and the connection terminal portion 156 of the probes 150 are allowed to extend beyond the edge of the supporter 140 that are to face the printed circuit board 110 when they are assembled together.

In one embodiment, the insulating resin 170 is applied to the insertion slots 146 to fix the probes 150 to the supporter 140. For example, the insulating resin 170 is first applied to the insertion slots 146 of the supporter 140, and then the first and second arm portions 152 and 154 of the probes 150 are inserted and fitted into the corresponding one of the insertion slots 146. In another embodiment, the insulating resin 170 is first applied to at least one of the first and second arm portions 152 and 154, and then the first and second arm portions 152 and 154 are inserted and fitted into the corresponding one of the insertion slots 146. Once the insulating resin 170 is fully cured, the first and second arm portions 152 and 154 are secured in the insertion slots 146.

As illustrated in FIG. 3, once the first and second arm portions 152 and 154 of each probe 150 are fitted to the insertion slots 146, the first recess 160 and the first hinge portion 162 are positioned at an outer corner portion of the banks 142a and 142b. This means that the probes 150 can be properly fitted to the insertion slots 146 of the supporter 140, even when the outer corner portions of the banks 142a and 142b have a machining error or when there exists a fabricating error between the supporter 140 and the probes 150. For example, if the outer corner portions of the banks 142a and 142b are machined at an obtuse angle and not at a right angle, the first and second hinge portions 162 and 168 will be elastically deformed so that the probes 150 can be smoothly fitted to the insertion slots 146.

After the probe assemblies 130 have been fabricated in this manner, the holder bracket 180 is attached to the lower surface of the printed circuit board 110 using screws 182 and then the probe assemblies 130 are positioned into the opening 184 of the holder bracket 180. Subsequently, the screws 114 are tightened into the screw holes 148 of the supporter 140 through the printed circuit board 110, thereby fixing the supporter 140 to the lower surface of the printed circuit board 110.

At this time, the connection terminal portions 156 of the probes 150 are electrically connected to the electrode pads 112 of the printed circuit board 110. As the first terminal 156b of the connection terminal portion 156 comes into contact with the electrode pads 112, the spring 156a is compressed to ensure that the first terminal 156b can be kept stably connected to the electrode pads 112 under the biasing force of the spring 156a. This helps prevent defective connection between the probes 150 and the electrode pads 112 of the printed circuit board 110 from occurring.

With the features of the probe card 100 described above, the first terminals 156b of the probes 150 is kept in mechanical contact with the electrode pads 112 of the printed circuit board 110 by the elastic deformation of the spring 156a. This eliminates the need for soldering the probes 150 to the printed circuit board 110, thereby greatly increasing the productivity and reliability of the probe card 100.

Furthermore, since the first and second arm portions 152 and 154 of each of the probes 150 are fitted to the corresponding one of the insertion slots 146, the probe card 100 of the present invention does not require the use of a jig for positioning the probes 150 in the fabricating process. Therefore, it is possible to easily and accurately fabricate the probe assemblies 130, which assists in greatly increasing the productivity of the probe card 100.

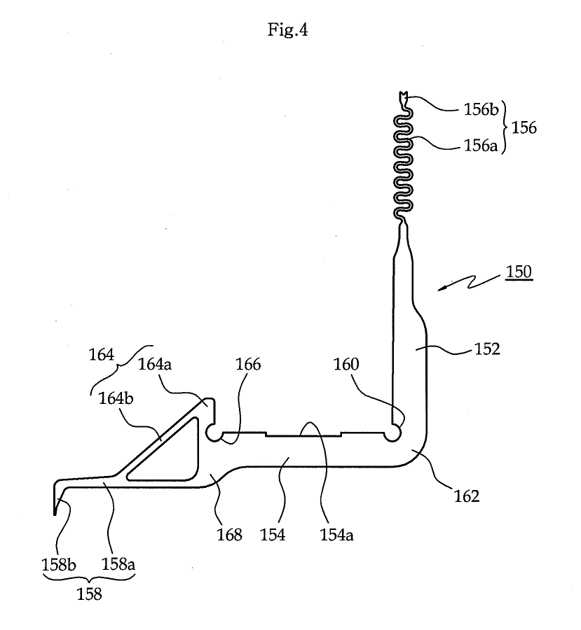

Referring to FIGS. 3 and 4, the resilient arm 158a undergoes elastic deformation when the second terminal 158b of each of the probes 150 is brought into contact with and pressed by the corresponding electrode pad 4 of the inspection object 2 when the inspection object 2 is placed for testing with the probe card 100 of the present invention. Thus, each of the electrode pads 4 of the inspection object 2 is kept in close contact with the second terminal 158b. At this time, the connecting arm portion 164b of the reinforcing portion 164 prevents plastic deformation of the resilient arm 158a by supporting the middle portion of the resilient arm 158a. This helps increase the life span of the probes 150, thereby improving the reliability thereof.

In case one of the probe assemblies 130 is or becomes defective, only the defective probe assembly can be replaced with a new probe assembly as there is no soldering between the printed circuit board 110 and the probe assembly or probe therein. This helps save the cost involved in maintaining and repairing the probe card 100.

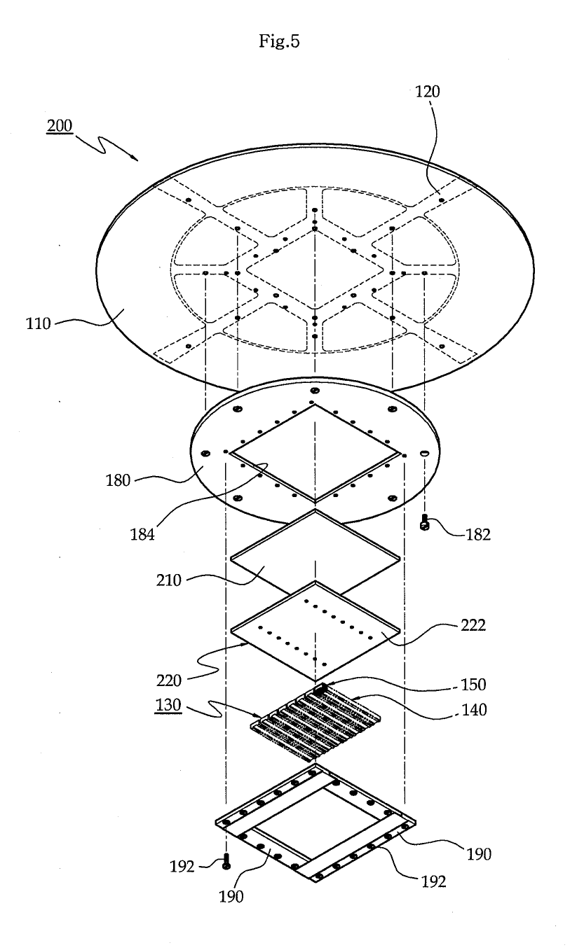

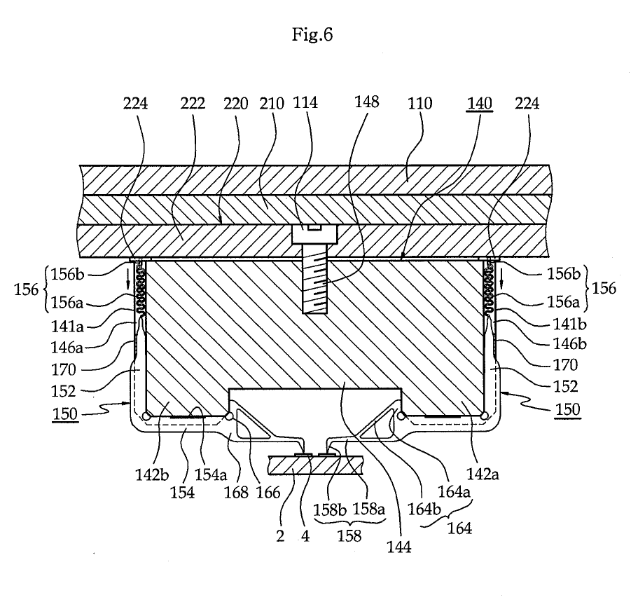

FIGS. 5 and 6 show a probe card in accordance with another embodiment of the present invention. Referring to FIGS. 5 and 6, the probe card 200 includes a printed circuit board 110, a stiffener 120, a plurality of probe assemblies 130, a holder bracket 180, a plurality of guard members 190, an interposer 210 and a space transformer 220. The printed circuit board 110, the stiffener 120, the plurality of probe assemblies 130, the holder bracket 180 and the plurality of guard members 190 are the same or almost the same as those of the probe card 100 of FIGS. 1-4. For this reason, the same components will be designated by like reference numerals but no description will be made in that regard.

The interposer 210 is received within the space or opening 184 of the holder bracket 180 to transmit electric signals and also to keep the probe card 200 planar. The space transformer 220 is mounted below the interposer 210. The space transformer 220 is formed of a multilayer printed circuit board 222 that includes a plurality of electrode pads 224 electrically connected to the printed circuit board 110 through the interposer 210.

The probe card 200 in accordance with the embodiment of the present invention is fabricated in the following manner. The probes 150 are fitted to the insertion slots 146 of the supporter 140 and fixedly secured thereto using, for example, an insulating resin 170. Then, the holder bracket 180 is attached to the lower surface of the printed circuit board 110. The interposer 210 and the multilayer printed circuit board 222 are received within the space 184 of the holder bracket 180 one after the other. Subsequently, the probe assemblies 130 are positioned below the multilayer printed circuit board 222 and the screws 114 are tightened into the screw holes 148 through the multilayer printed circuit board 222. At this time, the connection terminal portions 156 of the probes 150 are inserted and connected to the electrode pads 224 of the multilayer printed circuit board 222. Finally, the guard members 190 are attached to the lower surface of the holder bracket 180 using, for example, screws 192 so that they can surround the edge portions of supporters 140.

In the probe card 200 of the embodiment configured as above, electric signals are transmitted between the printed circuit board 110 and the probes 150 through the interposer 210 and the multilayer printed circuit board 222. In case the probes 150 are arranged at high density, they can be easily connected to the printed circuit board 110 by use of an interlayer conductor circuit (not shown) provided in the multilayer printed circuit board 222. This means that the probe card 200 of the embodiment is very useful in testing a semiconductor element with densely arranged electrode pads.

As described hereinabove, the probe card in accordance with the present invention is of a structure in which the probes are inserted and fitted into the insertion slots of the insulating supporter. Therefore, the probe card can be fabricated in an easy and accurate manner, which leads to reduced production cost and greatly increased productivity.

Furthermore, the present probe card is formed of the probe assemblies whose supporters and probes can be readily removed from the printed circuit board. This makes it possible to replace a defective probe assembly on an assembly-by-assembly basis, which assists in saving maintenance and repair cost.

In addition, the present probe card exhibits improved reliability because the probes thereof are capable of assuring stable connection between the inspection object and the printed circuit board.

The present invention is not limited to the embodiments set forth hereinabove. It will be understood by those skilled in the art that various changes and modifications may be made without departing from the scope of the invention defined in the claims.

What is claimed is:

1. A probe card for electrical testing, the probe card comprising:
a printed circuit board;
a first electrode electrically connected to the printed circuit board;
a probe supporter comprising a first side surface and a first bottom surface;
a plurality of insertion slots formed into at least one of the first side surface and the first bottom surface of the support;
a plurality of probes, a first one of the plurality of probes comprising:
a first arm extending along the first side surface,
a second arm connected to the first arm and extending along the first bottom surface,
a first terminal portion formed at a distal end of the first arm and comprising a first tip configured to contact the first electrode, and
a second terminal portion formed at a distal end of the second arm and comprising a second tip configured to contact a second electrode,
wherein at least part of the first and second arms is inserted into a first one of the plurality of insertion slots.

2. The probe card of claim 1, wherein the first insertion slot comprises a first slot portion formed into the first side surface and a second slot portion formed into the first bottom surface, wherein a portion of the first arm is received in the first slot portion, and wherein a portion of the second arm is received in the second slot portion.

3. The probe card of claim 1, further comprising:
a space transformer placed between the printed circuit board and the supporter, wherein the first electrode belongs to the space transformer while electrically connected to the printed circuit board.

4. The probe card of claim 3, further comprising an interposer placed between the printed circuit board and the space transformer for electrically interconnecting the printed circuit board and the space transformer.

5. The probe card of claim 1, wherein the second electrode belongs to an object for a test using the probe card.

6. The probe card of claim 1, wherein the supporter comprises a first bank and a second bank, the first bank comprising the first bottom surface, the second bank comprising a second bottom surface, wherein the first and second banks are spaced apart from each other and form a channel therebetween.

7. The probe card of claim 6, wherein the supporter further comprises a second side surface, wherein the probe card further comprises a plurality of insertion slots formed into at least one of the second side surface and the second bottom surface, wherein at least part of a second one of the plurality of probes is inserted into one of the insertion slots formed in the second side surfaced and the second bottom surface.

8. The probe card of claim 1, wherein the second arm comprises an upper surface facing the first bottom surface, wherein the second arm comprises a recessed portion in the upper surface so as to reduce a physical contact between the first bottom surface and the upper surface of the second arm.

9. The probe card of claim 1, wherein the first probe further comprises a first elastically deformable hinge portion generally in a juncture where the first and second arms meet with each other.

10. The probe card of claim 1, wherein the first terminal portion further comprises a spring between the first arm and the first tip.

11. The probe card of claim 1, wherein the second terminal portion comprises a resilient extension between the second arm and the second tip.

12. The probe card of claim 11, wherein the second terminal portion further comprises a reinforcing portion configured to reinforce the resilient extension such that the resilient extension can maintain its original configuration when no external force is exerted onto the resilient extension.

13. The probe card of claim 12, wherein the reinforcing portion comprises a first extension and a second extension that form a generally triangular configuration together with at least part of the resilient extension.

14. The probe card of claim 13, wherein the first extension extends from about the distal end of the second arm generally perpendicular to the second arm, wherein second extension interconnects the first extension and a mid portion of the resilient extension.

15. The probe card of claim 14, wherein the first probe further comprises a second elastically deformable hinge portion generally in a juncture where the second arm and the first extension meet with each other.

16. The probe card of claim 1, wherein the first probe is fixed to the insertion slot by means of an insulating resin.

17. A probe assembly for electrical testing, the probe assembly comprising:
a probe supporter comprising a first side surface and a first bottom surface;
a plurality of insertion slots formed into at least one of the first side surface and the first bottom surface of the support;
a plurality of probes, wherein a first one of the plurality of probes comprising:
a first arm extending along the first side surface,
a second arm connected to the first arm and extending along the first bottom surface,
a first terminal portion formed at a distal end of the first arm and comprising a first tip configured to contact one of a plurality of electrode pads, wherein the first tip is not fixed to the electrode pad while contacting thereto, and
a second terminal portion formed at a distal end of the second arm and comprising a second tip configured to contact an electrode of a testing object,
wherein at least part of the first and second arms is inserted into a first one of the plurality of insertion slots.

18. A probe for use in a probe card for electrical testing, the probe comprising:
a first arm extending generally in a first direction;
a second arm connected to the first arm and extending generally in a second direction other than the first direction;
a first terminal portion formed at a distal end of the first arm and comprising a first tip configured to form an electrical and physical contact with an electrode of a first device, wherein the first terminal portion is configured to allow the first tip to elastically move generally in the first direction; and
a second terminal formed at a distal end of the second arm and comprising a second tip configured to form an electrical and physical contact with an electrode of a second device, wherein the second terminal portion is configured to allow the second tip to elastically move generally in the first direction.

19. The probe of claim 18, wherein the second arm has an upper surface and a cutout formed into the upper surface.

20. The probe of claim 18, further comprising a first elastically deformable hinge provided generally at a juncture where the first and second arms meet with each other.

21. The probe of claim 18, wherein the first terminal portion comprises a spring between the first arm and the first tip, wherein the spring is configured to allow elastic movement of the first tip generally in the first direction.

22. The probe of claim 18, wherein the second terminal portion comprises a resilient extension between the second arm and the second tip.

23. The probe of claim 22, wherein the second terminal portion further comprises a reinforcing portion configured to reinforce the resilient extension such that the resilient extension can maintain its original configuration when no external force is exerted onto the resilient extension.

24. The probe of claim 23, wherein the reinforcing portion comprises a first extension and a second extension that form a generally triangular configuration together with at least part of the resilient extension.

25. The probe of claim 24, wherein the first extension extends from about the distal end of the second arm generally perpendicular to the second arm, wherein second extension interconnects the first extension and a mid portion of the resilient extension.

26. The probe of claim 25, wherein the first probe further comprises a second elastically deformable hinge portion generally in a juncture where the second arm and the first extension meet with each other.
